(19) United States
(12) Patent Application Publication
(10) Pub. No.: US 2025/0294820 A1
(43) Pub. Date: Sep. 18, 2025

(54) METHOD FOR MANUFACTURING SEMICONDUCTOR DEVICE

(71) Applicant: DENSO CORPORATION, Kariya-city (JP)

(72) Inventor: Hidefumi TAKAYA, Kariya-city (JP)

(21) Appl. No.: 19/226,590

(22) Filed: Jun. 3, 2025

Related U.S. Application Data
(63) Continuation of application No. PCT/JP2023/033261, filed on Sep. 12, 2023.

(30) Foreign Application Priority Data
Dec. 7, 2022 (JP) 2022-195678

(51) Int. Cl. H10D 62/00; H01L 21/66; H10D 30/01

(52) U.S. Cl. CPC H10D 62/054; H01L 22/12; H10D 30/0291

(57) ABSTRACT

In a method for manufacturing a semiconductor device having a semiconductor layer formed with a super junction structure in which an n-type column and a p-type column are alternately and repeatedly arranged at least in one direction, the super junction structure is formed in the semiconductor layer based on a pattern deviation of a shielding layer formed on a surface of the semiconductor layer relative to a design pattern, the shielding layer having an opening corresponding to at least one of an n-type column formation range where the n-type column is to be formed or a p-type column formation range where the p-type column is to be formed.

### CROSS REFERENCE TO RELATED APPLICATIONS

The present application is a continuation application of International Patent Application No. PCT/JP2023/033261 filed on Sep. 12, 2023, which designated the U.S. and claims the benefit of priority from Japanese Patent Application No. 2022-195678 filed on Dec. 7, 2022. The entire disclosures of all of the above applications are incorporated herein by reference.

### TECHNICAL FIELD

The present disclosure relates to a method for manufacturing a semiconductor device.

### BACKGROUND

As a structure of a semiconductor device that achieves both low on-resistance and high breakdown voltage, a super junction structure in which an n-type column and a p-type column are alternately and repeatedly arranged in at least one direction has been proposed.

### SUMMARY

The present disclosure describes a method for manufacturing a semiconductor device having a semiconductor layer formed with a super junction structure in which an n-type column and a p-type column are alternately and repeatedly arranged in at least one direction. According to an aspect, a method for manufacturing a semiconductor device may include forming a super junction structure in a semiconductor layer based on a pattern deviation of a shielding layer formed on a surface of the semiconductor layer relative to a design pattern, the shielding layer having an opening corresponding to at least one of an n-type column formation range where the n-type column is to be formed or a p-type column formation range where the p-type column is to be formed.

### BRIEF DESCRIPTION OF DRAWINGS

Features and advantages of the present disclosure will become more apparent from the following detailed description made with reference to the accompanying drawings, in which:

FIG. 1 is a schematic cross-sectional view of a main part of a semiconductor device according to an embodiment of the present disclosure;

FIG. 2 is a flowchart showing a process of forming a super junction structure in a first manufacturing method for manufacturing the semiconductor device shown in FIG. 1;

FIG. 3 is a schematic cross-sectional view of a main part in a process of the first manufacturing method for manufacturing the semiconductor device shown in FIG. 1;

FIG. 4 is a schematic cross-sectional view of a main part in a process of the first manufacturing method for manufacturing the semiconductor device shown in FIG. 1;

FIG. 5 is a schematic cross-sectional view of a main part in a process of the first manufacturing method for manufacturing the semiconductor device shown in FIG. 1;

FIG. 6 is a flowchart showing a process of forming a super junction structure in a modified example of the first manufacturing method for manufacturing the semiconductor device shown in FIG. 1;

FIG. 7 is a flowchart showing a process of forming a super junction structure in a second manufacturing method for manufacturing the semiconductor device shown in FIG. 1;

FIG. 8 is a schematic cross-sectional view of a main part in a process of the second manufacturing method for manufacturing the semiconductor device shown in FIG. 1;

FIG. 9 is a schematic cross-sectional view of a main part in a process of the second manufacturing method for manufacturing the semiconductor device shown in FIG. 1;

FIG. 10 is a schematic cross-sectional view of a main part in a process of the second manufacturing method for manufacturing the semiconductor device shown in FIG. 1;

FIG. 11 is a schematic cross-sectional view of a main part in a process of the second manufacturing method for manufacturing the semiconductor device shown in FIG. 1; and

FIG. 12 is a flowchart showing a process of forming a super junction structure in a third manufacturing method for manufacturing the semiconductor device shown in FIG. 1.

### DETAILED DESCRIPTION

In a semiconductor device having a super junction structure in which an n-type column and a p-type column are alternately and repeatedly arranged at least in one direction, in order to further improve the balance between low on-resistance and high breakdown voltage, it is necessary to increase the impurity concentration of the n-type column and the impurity concentration of the p-type column. However, in a case where the impurity concentrations of the n-type column and p-type column are both high, it is difficult to form the n-type column and p-type column, for example, by counter-doping p-type impurity ions into an n-type semiconductor layer. This is because a large number of p-type impurity ions needs to be ion-implanted into the n-type semiconductor layer having the high impurity concentration, which may cause issues such as defects. Therefore, in order to manufacture a semiconductor device having both the low on-resistance and the high breakdown voltage, it is necessary to form each of the n-type columns and p-type columns by ion implantation.

In a case where each of the n-type column and the p-type column is formed by the ion implantation, it is necessary a technique of controlling the impurity concentration and/or position of each of the n-type column and p-type column to suppress the disruption of the charge balance between the n-type column and p-type column. The present disclosure provides a technique that suppresses the disruption of the charge balance between the n-type column and the p-type column in the semiconductor device having the super junction structure.

A method according to an aspect of the present disclosure is for manufacturing a semiconductor device having a semiconductor layer formed with a super junction structure in which an n-type column and a p-type column are alternately and repeatedly arranged at least in one direction. The method includes forming the super junction structure in the semiconductor layer based on a pattern deviation of a shielding layer formed on a surface of the semiconductor layer relative to a design pattern, the shielding layer having an opening corresponding to at least one of an n-type column formation range where the n-type column is to be formed or a p-type column formation range where the p-type column is to be formed. The pattern deviation is not particularly limited, but may be, for example, a dimensional deviation of a width of the opening of the shielding layer, or a misalignment of the shielding layer. According to the method described above, the super junction structure can be formed through a feedback control based on the pattern deviation of the shielding layer. Therefore, it is possible to suppress the disruption of the charge balance between the n-type column and the p-type column.

A semiconductor device of the present disclosure will be described hereinafter with reference to the drawings. It should be noted that, for the element that is repeatedly arranged, a reference numeral is assigned to only one for the sake of clarity in the drawings.

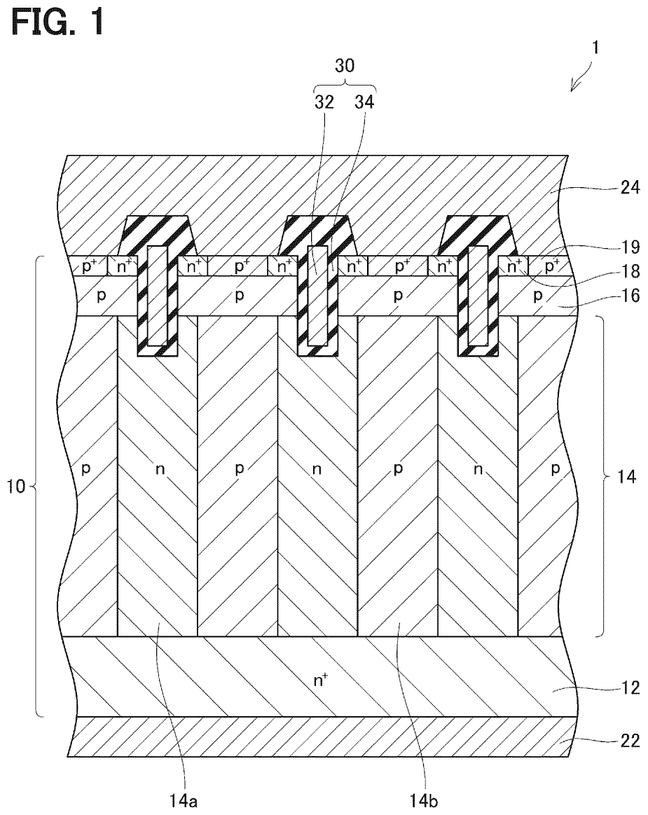

FIG. 1 schematically shows a cross-sectional view of a main part of a semiconductor device 1. The semiconductor device 1 is a power semiconductor device of a type which is referred to as a metal oxide semiconductor field effect transistor (MOSFET). The semiconductor device 1 includes a semiconductor layer 10, a drain electrode 22 covering a lower surface of the semiconductor layer 10, a source electrode 24 covering an upper surface of the semiconductor layer 10, and a plurality of trench gates 30 disposed in an upper layer portion of the semiconductor layer 10.

The semiconductor layer 10 is not particularly limited, but may be, for example, a 4H silicon carbide layer. The semiconductor layer 10 may have an upper surface with a crystal plane inclined by an off angle with respect to a (0001) Si plane. The off angle is not particularly limited, but may be, for example, 4°. The semiconductor layer 10 may be a silicon layer, a nitride semiconductor layer, or a gallium oxide layer, in place of the silicon carbide layer. The semiconductor layer 10 includes an n⁺-type drain region 12, an n-type drift region 14, a p-type body region 16, an n⁺-type source region 18, and a p⁺-type body contact region 19.

The drain region 12 is disposed in a lower layer portion of the semiconductor layer 10. The drain region 12 is disposed at a position exposed on the lower surface of the semiconductor layer 10. The drain region 12 is in ohmic contact with the drain electrode 22 that covers the lower surface of the semiconductor layer 10.

The drift region 14 is disposed between the drain region 12 and the body region 16. The drift region 14 includes a plurality of n-type columns 14a and a plurality of p-type columns 14b. The n-type columns 14a and the p-type columns 14b are arranged alternately at least in one direction in a repeating manner in a cross-section of the semiconductor layer 10 to form a super junction structure. Hereinafter, the direction in which the n-type columns 14a and the p-type columns 14b are arranged alternately in the repeating manner in the cross-section of the semiconductor layer 10 will be referred to as a “repetition direction”. Although not particularly limited, the n-type columns 14a and the p-type columns 14b may be arranged in a stripe pattern, when viewed in a direction perpendicular to the upper surface of the semiconductor layer 10, that is, in a plan view.

When the drift region 14 is depleted, the n-type columns 14a are positively charged, and the p-type columns 14b are negatively charged. When the amount of positive charge in the n-type columns 14a and the amount of negative charge in the p-type columns 14b are balanced, the drift region 14 is properly depleted, thereby improving the breakdown voltage of the semiconductor device 1. The semiconductor device 1 is designed so as to ensure the charge balance between the n-type columns 14a and the p-type columns 14b.

The body region 16 is disposed on the drift region 14. The body region 16 is located in the upper layer portion of the semiconductor layer 10. The body region 16 is disposed between the n-type columns 14a of the drift region 14 and the source region 18. The body region 16 is in contact with both the n-type columns 14a and the source region 18. The body region 16 separates the n-type columns 14a from the source region 18. The carrier concentration of the p-type impurity in the body region 16 is adjusted according to a desired gate threshold voltage.

The source region 18 is disposed on the body region 16. The source region 18 is located in the upper layer portion of the semiconductor layer 10. The source region 18 is located at a position exposed on the surface of the semiconductor layer 10. The source region 18 is in contact with side surfaces of the trench gate 30. The source region 18 is in ohmic contact with the source electrode 24, which covers the surface of the semiconductor layer 10.

The body contact region 19 is disposed on the body region 16. The body contact region 19 is located in the upper layer portion of the semiconductor layer 10. The body contact region 19 is located at a position exposed on the surface of the semiconductor layer 10. The body contact region 19 is in ohmic contact with the source electrode 24, which covers the surface of the semiconductor layer 10.

The trench gate 30 is filled in a trench formed in the upper layer portion of the semiconductor layer 10. The trench gate 30 penetrates the source region 18 and the body region 16, and reaches the n-type column 14a of the drift region 14. In this example, the trench gate 30 extends along longitudinal directions of the n-type columns 14a and the p-type columns 14b, when the semiconductor layer 10 is viewed from above, that is, in the plan view. Alternative to this example, the trench gate 30 may extend in the repetition direction of the n-type columns 14a and the p-type columns 14b, that is, in a direction perpendicular to the longitudinal directions of the n-type columns 14a and the p-type columns 14b, when the semiconductor device 10 is viewed from above, that is, in the plan view. The trench gate 30 includes a gate electrode 32 and a gate insulating film 34. The gate electrode 32 is formed of polysilicon containing impurities. The gate electrode 32 faces the semiconductor layer 10 through the gate insulating film 34. Specifically, the gate electrode 32 faces a portion of the body region 16 through the gate insulating film 34, the portion separating the n-type column 14a of the drift region 14 from the source region 18. The gate insulating film 34 is formed of a silicon oxide. The gate insulating film 34 covers the inner wall of the trench.

Next, an operation of the semiconductor device 1 will be described with reference to FIG. 1. In a state where the potential of the drain electrode 22 is more positive than the potential of the source electrode 24, when the potential of the gate electrode 32 of the trench gate 30 is controlled to be more positive than the source electrode 24 and higher than the threshold value, the semiconductor device 1 turns on. At this time, an inversion layer is formed in the portion of the body region 16, the portion separating the source region 18 from the n-type column 14a of the drift region 14. Electrons supplied from the source region 18 reach the n-type column 14a of the drift region 14 via the channel of the inversion layer. The electrons that have reached the n-type column 14a flow to the drain region 12 from the n-type column 14a. Since the n-type column 14a has the high carrier concentration of the n-type impurity, the semiconductor device 1 can have the characteristic of low on-resistance.

When the potential of the gate electrode 32 of the trench gate 30 is controlled to be the same as the potential of the source electrode 24, the channel of the inversion layer disappears, and the semiconductor device 1 turns off. The plurality of n-type columns 14a and the plurality of p-type columns 14b, which form the super junction structure, are substantially fully depleted. As a result, the drift region 14 is depleted in a wide area. Since the drift region 14 has the super junction structure, the electric field distribution in the drift region 14 is leveled in the thickness direction. Since the drift region 14 can withstand a large potential difference, the semiconductor device 1 can thus have the characteristic of high breakdown voltage.

### (First Manufacturing Method of Semiconductor Device)

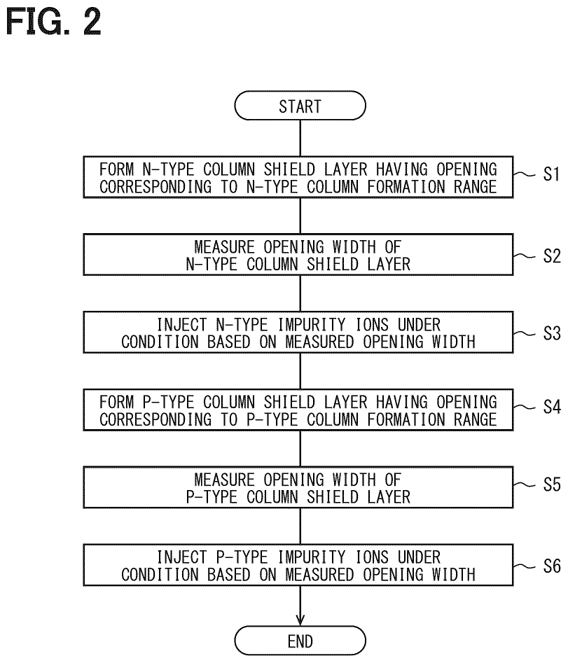

Next, a process of forming the super junction structure in a first manufacturing method for manufacturing the semiconductor device 1 will be described with reference to FIGS. 2 to 5. Other processes of the first manufacturing method for manufacturing the semiconductor device 1 can employ known manufacturing techniques.

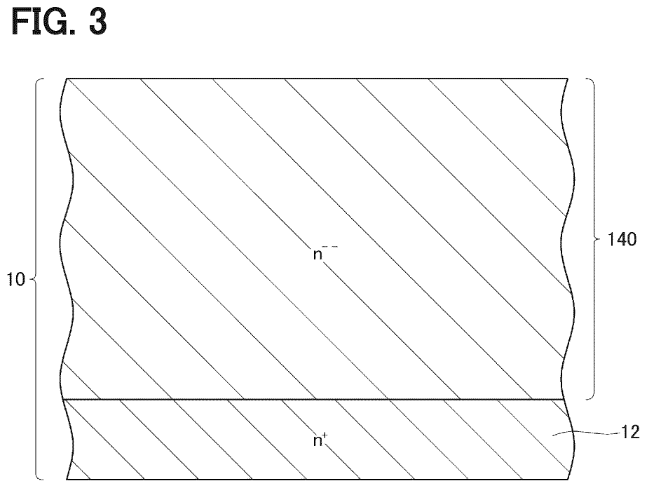

First, as shown in FIG. 3, the drain region 12, which is composed of the n⁺-type silicon carbide substrate, is prepared. Next, the n-type epitaxial layer 140 of silicon carbide is grown from the surface of the drain region 12 by an epitaxial growth technique, such as a chemical vapor deposition (CVD), though not particularly limited. The epitaxial layer 140 forms at least a part of the semiconductor layer 10. The epitaxial layer 140 may also be referred to as the semiconductor layer.

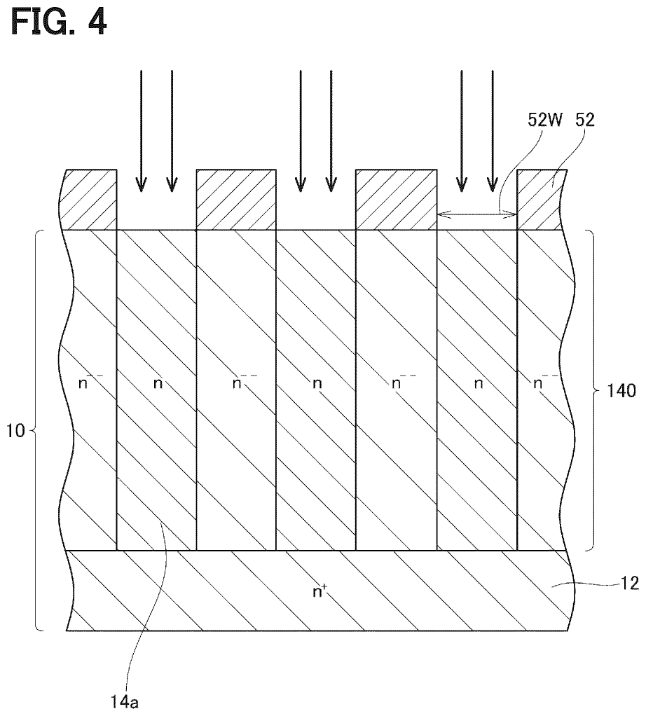

Next, as shown in FIG. 4, an n-type column shielding layer 52 is formed on the epitaxial layer 140 using a photolithography technique (i.e., S1 in FIG. 2). The n-type column shielding layer 52 is patterned to have openings corresponding to ranges where the n-type columns 14a are to be formed, which may also be referred to as n-type column formation ranges.

Next, an opening width 52W of the n-type column shielding layer 52 is measured (i.e., S2 in FIG. 2). The opening width 52W is the width of the opening of the n-type column shielding layer 52 in a short side direction of the opening and corresponds to the width of the opening in the repetition direction of the super junction structure.

Next, the n-type columns 14a are formed by implanting n-type impurity ions into the epitaxial layer 140 through the openings of the n-type column shielding layer 52 using an ion implantation technique (i.e., S3 in FIG. 2). Although the n-type impurity ions are not particularly limited, nitrogen ions may be used, for example. Here, a condition for implanting the n-type impurity ions is set based on the measured opening width 52W of the n-type column shielding layer 52. When the measured opening width 52W is smaller than the opening width of a design pattern, the ion implantation process of the n-type impurity ions is performed under a condition where a condition of the implantation dose of the n-type impurity ions is more than a design condition (i.e., a reference condition). On the other hand, when the measured opening width 52W is greater than the opening width of the design pattern, the ion implantation process of the n-type impurity ions is performed under a condition where the condition of the implantation dose of the n-type impurity ions is less than the design condition. In this manner, by feedback controlling the implantation dose of the n-type impurity ions based on a pattern deviation of the opening width 52W of the n-type column shielding layer 52, the concentration of the n-type impurity of the n-type column 14a can be set to a desired value. The implantation dose of the n-type impurity ions to be set can be adjusted continuously based on the opening width 52W, or can be adjusted in multiple stages. After the ion implantation, the n-type column shielding layer 52 is removed.

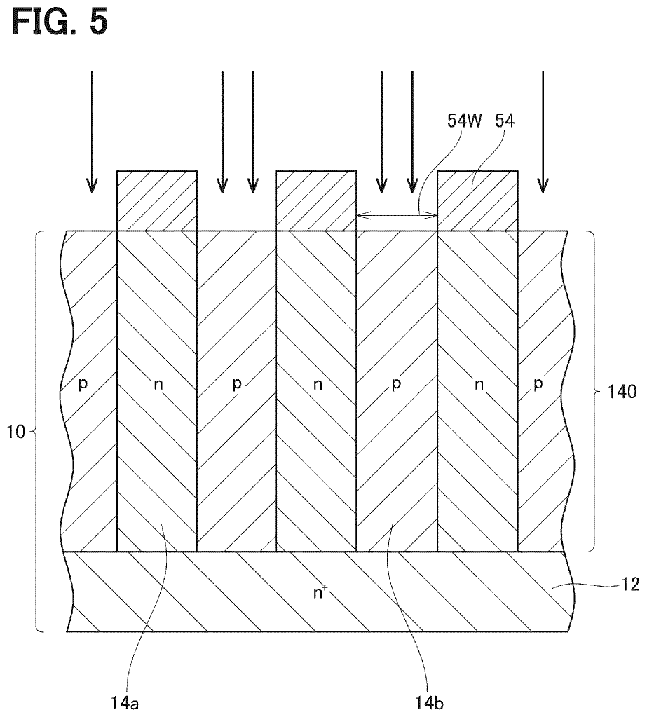

Next, as shown in FIG. 5, a p-type column shielding layer 54 is formed on the epitaxial layer 140 using a photolithography technique (i.e., S4 in FIG. 2). The p-type column shielding layer 54 is patterned to have openings corresponding to the ranges where the p-type columns 14b are to be formed, which may also be referred to as p-type column formation ranges.

Next, an opening width 54W of the p-type column shielding layer 54 is measured (i.e., S5 in FIG. 2). The opening width 54W is the width of the opening of the p-type column shielding layer 54 in the short side direction of the opening, and corresponds to the width of the opening in the repetition direction of the super junction structure.

Next, the p-type columns 14b are formed by implanting p-type impurity ions into the epitaxial layer 140 through the openings of the p-type column shielding layer 54 using an ion implantation technique (i.e., S6 in FIG. 2). Although the p-type impurity ions are not particularly limited, aluminum ions may be used, for example. In this case, a condition for implanting the p-type impurity ions is set based on the measured opening width 54W of the p-type column shielding layer 54. When the measured opening width 54W is smaller than the opening width of the design pattern, the ion implantation process of the p-type impurity ions is performed under a condition where the condition of the implantation dose of the p-type impurity ions is more than a design condition (i.e., a reference condition). On the other hand, when the measured opening width 54W is greater than the opening width of the design pattern, the ion implantation process of the p-type impurity ions is performed under a condition where the condition of the implantation dose of the p-type impurity ions is less than the design condition. In this manner, by feedback controlling the implantation dose of the p-type impurity ions based on the pattern deviation of the opening width 54W of the p-type column shielding layer 54, the concentration of the p-type impurity of the p-type columns 14b can be set to a desired value. The implantation dose of the p-type impurity ions to be set can be adjusted continuously based on the opening width 54W, or can be adjusted in multiple stages. After the ion implantation, the p-type column shielding layer 54 is removed.

Through these processes, the super junction structure having the n-type columns 14a and the p-type columns 14b alternately arranged in the repeating manner can be formed in the semiconductor layer 10. According to the manufacturing method described above, the impurity concentration of the n-type columns 14a and the impurity concentration of the p-type columns 14b are adjusted to the desired values through the feedback control. As a result, when the semiconductor device 1 is turned off, the amount of positive charge in the n-type columns 14a and the amount of negative charge in the p-type columns 14b are balanced, and the drift region 14 is properly depleted. Therefore, the semiconductor device 1 can have the characteristic of high breakdown voltage.

### Modified Example of First Manufacturing Method of Semiconductor Device

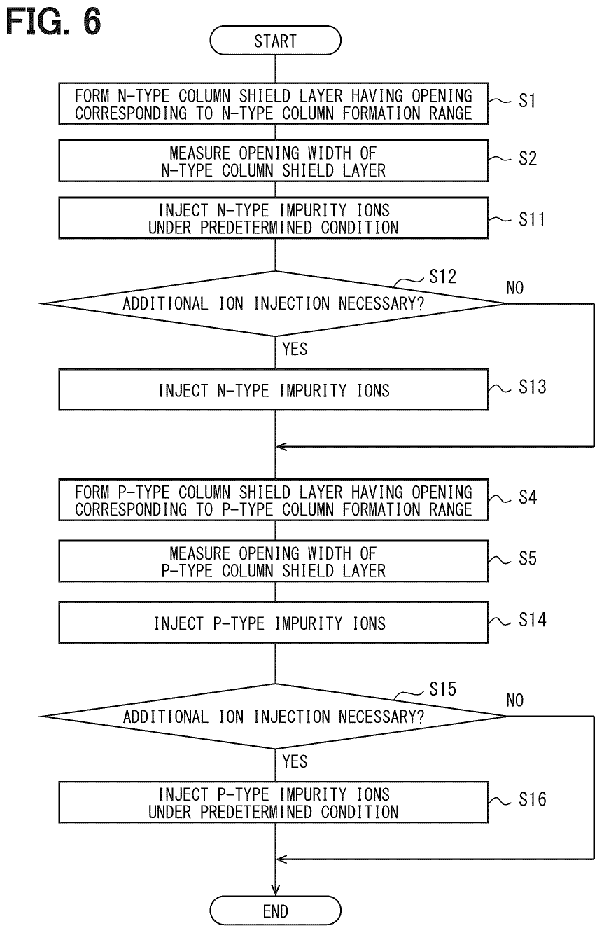

The manufacturing method described above is an example in which the ion implantation process is performed once for each of the n-type columns 14a and the p-type columns 14b, and the implantation dose of the impurity is adjusted for the ion implantation process performed once. Alternative to such an example, the ion implantation process may be performed once as a first ion implantation process under a predetermined condition set in advance, and the ion implantation process may be performed additionally as an additional ion implantation, only if necessary. FIG. 6 shows a manufacturing flow of this example. In the manufacturing flow shown in FIG. 6, the processes same as those in the flow of FIG. 2 are denoted by the same reference numerals.

As shown in FIGS. 6, S1 and S2 are the same as S1 and S2 in the manufacturing flow shown in FIG. 2. Next, n-type impurity ions are implanted into the epitaxial layer 140 through the openings of the n-type column shielding layer 52 using an ion implantation technique (i.e., S11 in FIG. 6). The n-type impurity ions are implanted under a predetermined condition set in advance. In this case, the predetermined condition is a condition in which the implantation dose of the n-type impurity ions is set so that an n-type impurity concentration is less than a desired n-type impurity concentration for the n-type columns 14a.

Next, it is determined whether or not the additional ion implantation is necessary based on the measured opening width 52W of the n-type column shielding layer 52 (i.e., S12 in FIG. 6). In this determination process, when the n-type impurity concentration of the n-type column 14a estimated from the measured opening width 52W of the n-type column shielding layer 52 and the predetermined condition of the first ion implantation process is equal to or lower than an acceptable concentration, it is determined that the additional ion implantation is necessary. When it is determined that the additional ion implantation is necessary, the n-type impurity ions are implanted into the epitaxial layer 140 through the openings of the n-type column shielding layer 52 to form the n-type columns 14a (i.e., S13 in FIG. 6). The implantation dose of the n-type impurity ions to be additionally implanted may be a predetermined condition set in advance. When it is determined that the additional ion implantation is not necessary, the additional ion implantation process is omitted. In this manner, by feedback controlling the number of implantation times of the n-type impurity ions based on the pattern deviation of the opening width 52W of the n-type column shielding layer 52, the n-type impurity concentration of the n-type columns 14a can be adjusted to the desired value. After the ion implantation, the n-type column shielding layer 52 is removed.

As shown in FIGS. 6, S4 and S5 are the same as S4 and S5 in the manufacturing flow shown in FIG. 2. Next, the p-type impurity ions are implanted into the epitaxial layer 140 through the openings of the p-type column shielding layer 54 using an ion implantation technique (i.e., S14 in FIG. 6). The p-type impurity ions are implanted under a predetermined condition set in advance. In this case, the predetermined condition is a condition in which the implantation dose of the p-type impurity ions is set so that a p-type impurity concentration is less than a desired p-type impurity concentration for the p-type columns 14b.

Next, it is determined whether or not the additional ion implantation is necessary based on the measured opening width 54W of the p-type column shielding layer 54 (i.e., S15 in FIG. 6). In this determination process, when the p-type impurity concentration of the p-type column 14b estimated from the measured opening width 54W of the p-type column shielding layer 54 and the predetermined condition of the first ion implantation process is equal to or lower than an acceptable concentration, it is determined that the additional ion implantation is necessary. When it is determined that the additional ion implantation is necessary, the p-type impurity ions are implanted into the epitaxial layer 140 through the openings of the p-type column shielding layer 54 to form the p-type columns 14b (i.e., S16 in FIG. 6). The implantation dose of the p-type impurity ions to be additionally implanted may be a predetermined condition set in advance. When it is determined that the additional ion implantation is not necessary, the additional ion implantation process is omitted. In this manner, by feedback controlling the number of implantation times of the p-type impurity ions based on the pattern deviation of the opening width 54W of the p-type column shielding layer 54, the p-type impurity concentration of the p-type columns 14b can be adjusted to the desired value. After the ion implantation, the p-type column shielding layer 54 is removed.

Through these processes, the super junction structure having the n-type columns 14a and the p-type columns 14b alternately arranged in the repeating manner is formed in the semiconductor layer 10. Also in the manufacturing method described above, the impurity concentrations of the n-type columns 14a and p-type columns 14b are adjusted to the desired values through the feedback control. Therefore, the semiconductor device 1 can have the characteristic of high breakdown voltage.

### (Second Manufacturing Method of Semiconductor Device)

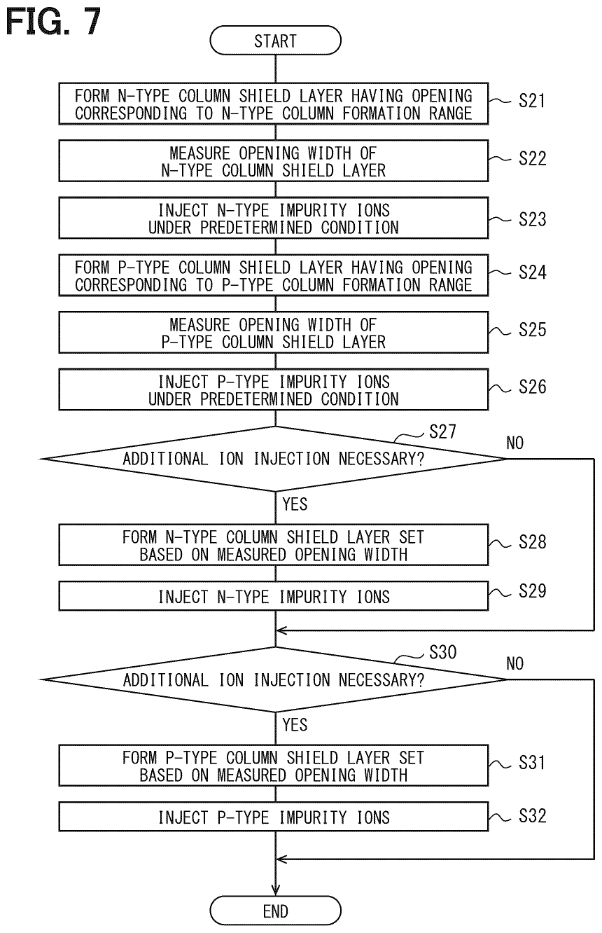

The first manufacturing method described above is an example in which a single shielding layer is used in the ion implantation process of each of the n-type columns 14a and the p-type columns 14b. Alternative to such an example, two shielding layers may be used in the ion implantation process of each of the n-type columns 14a and the p-type columns 14b. Referring to FIGS. 7 to 11, a process for forming the super junction structure in a second manufacturing method of the semiconductor device 1 will be described. Note that components same as those in the first manufacturing method are denoted by the same reference numerals, and descriptions thereof will not be repeated.

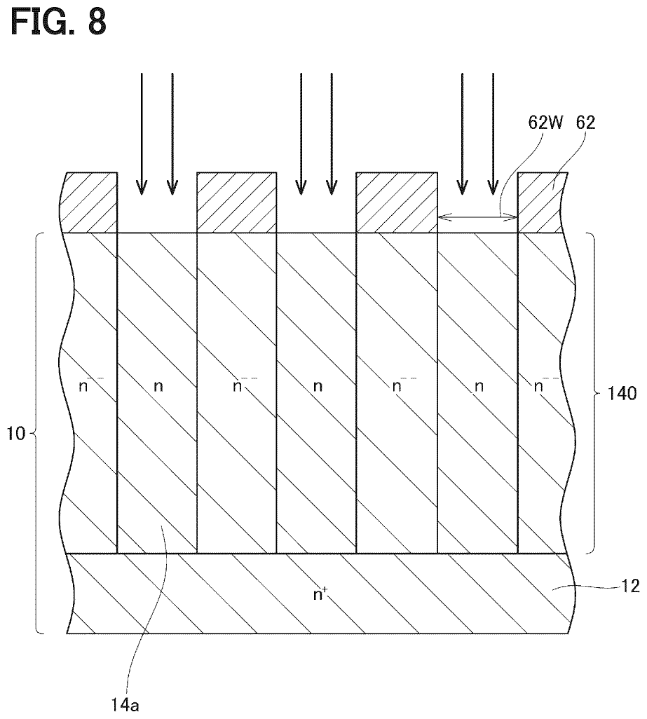

First, as shown in FIG. 8, an n-type column shielding layer 62 is formed on the epitaxial layer 140 using a photolithography technique (i.e., S21 in FIG. 7). The n-type column shielding layer 62 is patterned to have openings corresponding to the formation ranges where the n-type columns 14a are to be formed.

Next, an opening width 62W of the n-type column shielding layer 62 is measured (i.e., S22 in FIG. 7). The opening width 62W is the width of the opening of the n-type column shielding layer 62 in a short side direction of the opening and corresponds to the width of the opening in the repetition direction of the super junction structure.

Next, n-type impurity ions are implanted into the epitaxial layer 140 through the openings of the n-type column shielding layer 62 using an ion implantation technique (i.e., S23 in FIG. 7). The n-type impurity ions are implanted under a predetermined condition set in advance. In this case, the predetermined condition is a condition in which the implantation dose of the n-type impurity ions is set so that an n-type impurity concentration is less than a desired n-type impurity concentration for the n-type columns 14a. After the ion implantation, the n-type column shielding layer 62 is removed.

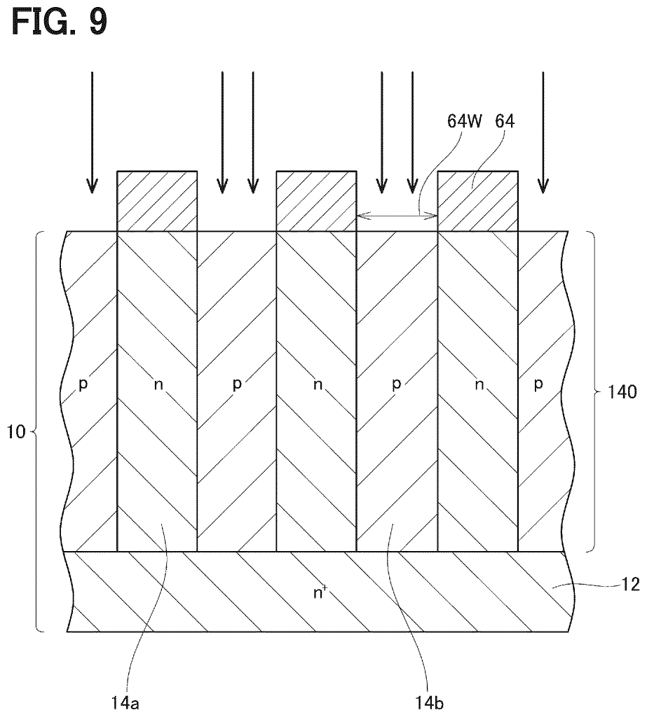

Next, as shown in FIG. 9, a p-type column shielding layer 64 is formed on the epitaxial layer 140 using a photolithography technique (i.e., S24 in FIG. 7). The p-type column shielding layer 64 is patterned to have openings corresponding to the formation ranges where the p-type columns 14b are to be formed.

Next, the opening width 64W of the p-type column shielding layer 64 is measured (i.e., S25 in FIG. 7). The opening width 64W is the width of the opening of the p-type column shielding layer 64 in a short side direction of the opening and corresponds to the width of the opening in the repetition direction of the super junction structure.

Next, p-type impurity ions are implanted into the epitaxial layer 140 through the openings of the p-type column shielding layer 64 using an ion implantation technique (i.e., S26 in FIG. 7). The p-type impurity ions are implanted under a predetermined condition set in advance. In this case, the predetermined condition is a condition in which the implantation dose of the p-type impurity ions is set so that the p-type impurity concentration is less than a desired p-type impurity concentration for the p-type columns 14b. After the ion implantation, the p-type column shielding layer 64 is removed.

Next, it is determined whether or not an additional ion implantation is necessary based on the opening width 62W of the n-type column shielding layer 62 measured in S22 (i.e., S27 in FIG. 7). In this determination process, when the n-type impurity concentration of the n-type column 14a estimated from the measured opening width 62W of the n-type column shielding layer 62 and the predetermined condition of the first ion implantation process is equal to or lower than an acceptable concentration, it is determined that the additional ion implantation is necessary.

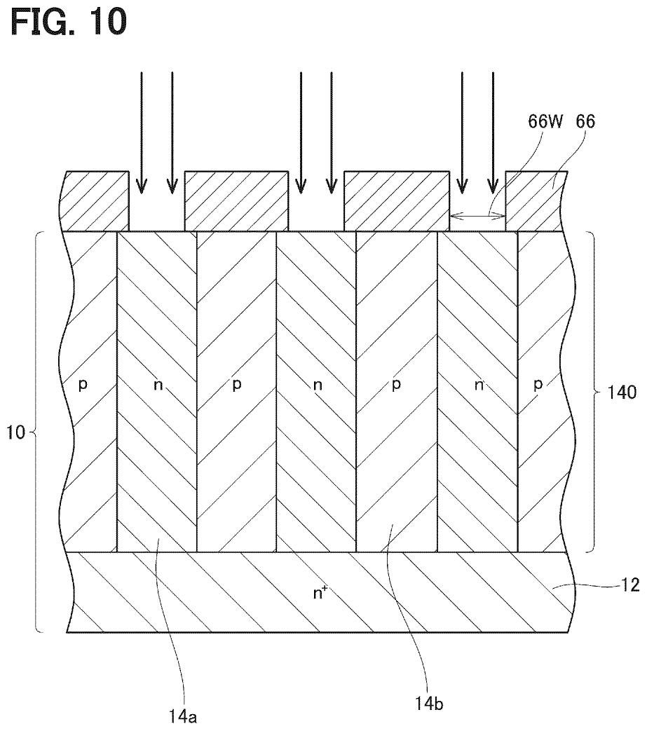

As shown in FIG. 10, when it is determined that the additional ion implantation is necessary, an additional n-type column shielding layer 66 is formed on the epitaxial layer 140 using a photolithography technique (i.e., S28 in FIG. 7). The additional n-type column shielding layer 66 is patterned to have openings each corresponding to a portion inside the formation range where the corresponding n-type column 14a is formed. As a result, even if there is a pattern deviation, the position of the opening of the additional n-type column shielding layer 66 can reliably fall within the region where n-type impurity ions have been implanted during the first ion implantation process. In this case, multiple types of photomasks for exposing the additional n-type column shielding layer 66 are prepared, and an appropriate type of photomask is selected according to the measured opening width 62W of the n-type column shielding layer 62 (see FIG. 8), that is, according to the implantation dose of the n-type impurity ions implanted during the first ion implantation process. For example, when the measured opening width 62W of the n-type column shielding layer 62 is greater than the design value, the implantation dose of the n-type impurity ions implanted during the first ion implantation process is more than the design value. In this case, therefore, the type of photomask in which the opening width 66W is smaller than the design value is selected for exposing the additional n-type column shielding layer 66. On the other hand, when the measured opening width 62W of the n-type column shielding layer 62 is smaller than the design value, the implantation dose of the n-type impurity ions implanted during the first ion implantation process is less than the design value. In this case, therefore, the type of photomask in which the opening width 66W is greater than the design value is selected for exposing the additional n-type column shielding layer 66.

Next, n-type impurity ions are implanted into the epitaxial layer 140 through the openings of the additional n-type column shielding layer 66 using an ion implantation technique to form the n-type columns 14a (i.e., S29 in FIG. 7). The n-type impurity ions may be implanted under a predetermined condition set in advance. In this manner, by feedback controlling the opening width 66W of the additional n-type column shielding layer 66 to be additionally formed based on the pattern deviation of the opening width 62W of the n-type column shielding layer 62, the n-type impurity concentration of the n-type columns 14a can be adjusted to a desired value. After the ion implantation, the additional n-type column shielding layer 66 is removed. When it is determined that the additional ion implantation is not necessary, these additional ion implantation processes are omitted.

Next, it is determined whether or not an additional ion implantation is necessary based on the opening width 64W of the p-type column shielding layer 64 measured in S25 (i.e., S30 in FIG. 7). In this determination process, when the p-type impurity concentration of the p-type column 14b estimated from the measured opening width 64W of the p-type column shielding layer 64 and the predetermined condition of the first ion implantation process is equal to or lower than the acceptable concentration, it is determined that the additional ion implantation is necessary.

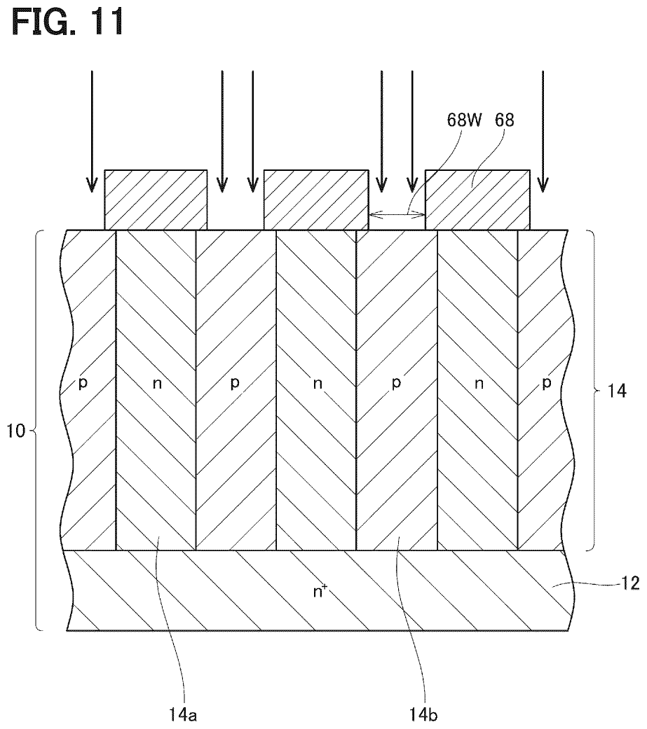

As shown in FIG. 11, when it is determined that the additional ion implantation is necessary, an additional p-type column shielding layer 68 is formed on the epitaxial layer 140 using a photolithography technique (i.e., S31 in FIG. 7). The additional p-type column shielding layer 68 is patterned to have openings each corresponding to a portion inside the range where the corresponding p-type column 14b is formed. As a result, even if there is a pattern deviation, the position of the opening of the additional p-type column shielding layer 68 can reliably fall within the region where the p-type impurity ions have been implanted during the first ion implantation process. In this case, multiple types of photomasks for exposing the additional p-type column shielding layer 68 are prepared, and an appropriate photomask is selected according to the measured opening width 64W of the p-type column shielding layer 64 (see FIG. 9), that is, according to the implantation dose of the p-type impurity ions implanted during the first ion implantation process. For example, when the measured opening width 64W of the p-type column shielding layer 64 is greater than the design value, the implantation dose of the p-type impurity ions implanted during the first ion implantation process is more than the design value. In this case, therefore, the type of photomask in which the opening width 68W smaller than the design value is selected for exposing the additional p-type column shielding layer 68. On the other hand, when the measured opening width 64W of the p-type column shielding layer 64 is smaller than the design value, the implantation dose of the p-type impurity ions implanted during the first ion implantation process is less than the design value. In this case, therefore, the type of photomask in which the opening width 68W is greater than the design value is selected for exposing the additional p-type column shielding layer 68.

Next, p-type impurity ions are implanted into the epitaxial layer 140 through the openings of the additional p-type column shielding layer 68 using an ion implantation technique to form the p-type column 14b (i.e., S32 in FIG. 7). The p-type impurity ions may be implanted under a predetermined condition set in advance. In this manner, by feedback controlling the opening width 68W of the additional p-type column shielding layer 68 to be additionally formed based on the pattern deviation of the opening width 64W of the p-type column shielding layer 64, the concentration of p-type impurities in the p-type column 14b can be set to the desired value. After the ion implantation, the additional p-type column shielding layer 68 is removed. When it is determined that the additional ion implantation is not necessary, these additional ion implantation processes are omitted.

Through these processes, the super junction structure in which the n-type columns 14a and the p-type columns 14b are alternately arranged in the repeating manner can be formed in the semiconductor layer 10. Also in the manufacturing method described above, the impurity concentrations of the n-type columns 14a and p-type columns 14b are adjusted to desired values through the feedback control. As a result, the semiconductor device 1 has the characteristic of high breakdown voltage.

According to the manufacturing method described above, it is possible to address for each chip in the wafer individually. The opening width of the shielding layer for the first ion implantation is measured for each chip, and the opening width of the shielding layer for the second ion implantation can be feedback-controlled for each chip. For the chip determined not to require the second ion implantation, the second ion implantation process can be omitted by refraining exposure of the shielding layer for the second ion implantation corresponding to such a chip. According to the manufacturing method described above, since the ion implantation can be addressed individually for each chip in the wafer, the impurity concentrations of the n-type columns 14a and the p-type columns 14b can be optimized for each chip.

### (Third Manufacturing Method of Semiconductor Device)

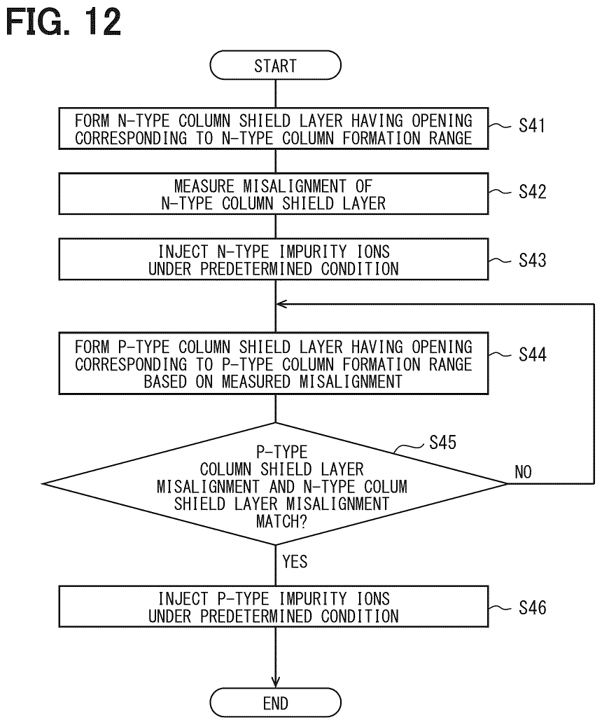

The first and second manufacturing methods described above are examples of feedback-controlling the ion implantation process based on the pattern deviation of the opening width of the shielding layer for the ion implantation. Alternative to these examples, the ion implantation process may be feedback-controlled based on a misalignment of the shielding layer for the ion implantation. Referring to a manufacturing flow shown in FIG. 12, a process for forming the super junction structure in a third manufacturing method of the semiconductor device 1 will be explained. Although the cross-sectional view is omitted, the cross-sectional view for explaining the third manufacturing method is, for example, similar to that of the first manufacturing method.

First, an n-type column shielding layer is formed on the epitaxial layer using a photolithography technique (i.e., S41 in FIG. 12). The n-type column shielding layer is patterned to have openings corresponding to the formation ranges where the n-type columns are to be formed.

Next, the misalignment of the n-type column shielding layer is measured (i.e., S42 in FIG. 12). The misalignment refers to a positional deviation from a design position in a relative positional relationship with respect to an alignment mark. Although not particularly limited, the misalignment may be, for example, described in a coordinate system defined with reference to the alignment mark. For example, in a case where an XY orthogonal coordinate system is defined with reference to the alignment mark, the misalignment can be described as a positional deviation of the two components in the X direction and the Y direction.

Next, the n-type columns are formed by implanting n-type impurity ions into the epitaxial layer through the openings of the n-type column shielding layer using ion implantation technique (i.e., S43 in FIG. 12). The n-type impurity ions may be implanted under a predetermined condition set in advance. After the ion implantation, the n-type column shielding layer is removed.

Next, a p-type column shielding layer is formed on the epitaxial layer using a photolithography technique (i.e., S44 in FIG. 12). In this case, the p-type column shielding layer is formed so as to have a similar misalignment to the n-type column shielding layer based on the measured misalignment of the n-type column shielding layer.

Next, the misalignment of the p-type column shielding layer is measured, and it is determined whether or not the measured misalignment of the p-type column shielding layer matches the misalignment of the n-type column shielding layer (i.e., S45 in FIG. 12). It should be noted that “matching” here does not only include a case where the misalignments between the p-type column shielding layer and the n-type column shielding layer completely match, but also includes a case where a difference between the misalignment of the p-type column shielding layer and the misalignment of the n-type column shielding layer is within an acceptable range.

When the misalignment of the p-type column shielding layer and the misalignment of the n-type column shielding layer match, p-type impurity ions are implanted into the epitaxial layer through the openings of the p-type column shielding layer using an ion implantation technique to form the p-type columns (i.e., S46 in FIG. 12). The p-type impurity ions may be implanted under a predetermined condition set in advance. Since the misalignment of the p-type column shielding layer matches the misalignment of the n-type column shielding layer, the relative positional relationship between the formed n-type columns and the formed p-type columns will be close to that of the design pattern. In this way, by feedback controlling the pattern of the p-type column shielding layer based on the misalignment of the n-type column shielding layer, the relative positional relationship between the n-type columns and the p-type columns can be made as desired. When the misalignment of the p-type column shielding layer does not match the misalignment of the n-type column shielding layer, the film formation process for the p-type column shielding layer may be performed again after the p-type column shielding layer is removed.

The process of feedback controlling the misalignment of the shielding layer may be performed together with the process of feedback controlling the opening width of the shielding layer. The p-type column shielding layer may be formed first, and the pattern of the n-type column shielding layer can be feedback controlled based on the misalignment of the p-type column shielding layer.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A method for manufacturing a semiconductor device that includes a semiconductor layer having a super junction structure in which an n-type column and a p-type column are alternately and repeatedly arranged in at least one direction, the method comprising:
forming the super junction structure in the semiconductor layer based on a pattern deviation of a shielding layer formed on a surface of the semiconductor layer relative to a design pattern, the shielding layer having an opening corresponding to at least one of an n-type column formation range where the n-type column is to be formed or a p-type column formation range where the p-type column is to be formed.

2. The method according to claim 1, wherein
the forming of the super junction structure includes:
forming the n-type column based on the pattern deviation of an n-type column shielding layer having an opening corresponding to the n-type column formation range; and
forming the p-type column based on the pattern deviation of a p-type column shielding layer having an opening corresponding to the p-type column formation range.

3. The method according to claim 2, wherein
the forming of the n-type column based on the pattern deviation of the n-type column shielding layer includes:
measuring a width of the opening of the n-type column shielding layer; and
implanting n-type impurity ions into the semiconductor layer through the opening of the n-type column shielding layer, and
the implanting of the n-type impurity ions includes adjusting an implantation dose of the n-type impurity ions according to the measured with of the opening of the n-type column shielding layer.

4. The method according to claim 2, wherein
the forming of the p-type column based on the pattern deviation of the p-type column shielding layer includes:
measuring a width of the opening of the p-type column shielding layer; and
implanting p-type impurity ions into the semiconductor layer through the opening of the p-type column shielding layer, and
the implanting of the p-type impurity ions includes adjusting an implantation dose of the p-type impurity ions according to the measured width of the opening of the p-type column shielding layer.

5. The method according to claim 2, wherein
the forming of the n-type column based on the pattern deviation of the n-type column shielding layer includes:
measuring a width of the opening of the n-type column shielding layer;
implanting n-type impurity ions into the semiconductor layer through the opening of the n-type column shielding layer according to a predetermined condition;
determining whether or not an additional implantation of the n-type impurity ions is necessary according to the measured width of the opening of the n-type column shielding layer; and
additionally implanting the n-type impurity ions into the semiconductor layer through the opening of the n-type column shielding layer when it is determined that the additional implantation of the n-type impurity ions is necessary.

6. The method according to claim 2, wherein
the forming of the p-type column based on the pattern deviation of the p-type column shielding layer includes:
measuring a width of the opening of the p-type column shielding layer;
implanting p-type impurity ions into the semiconductor layer through the opening of the p-type column shielding layer according to a predetermined condition;
determining whether nor not an additional implantation of the p-type impurity ions is necessary according to the measured width of the opening of the p-type column shielding layer; and
additionally implanting the p-type impurity ions into the semiconductor layer through the opening of the p-type column shielding layer when it is determined that the additional implantation of the p-type impurity ions is necessary.

7. The method according to claim 2, wherein
the forming of the n-type column based on the pattern deviation of the n-type column shielding layer includes:
measuring a width of the opening of the n-type column shielding layer;
implanting n-type impurity ions into the semiconductor layer through the opening of the n-type column shielding layer;
removing the n-type column shielding layer;
determining whether or not an additional implantation of the n-type impurity ions is necessary according to the measured width of the opening of the n-type column shielding layer;
forming an additional n-type column shielding layer having an opening corresponding to at least a portion of the n-type column formation range on the surface of the semiconductor layer, when it is determined that the additional implantation of the n-type impurity is necessary; and
implanting the n-type impurity ions into the semiconductor layer through the opening of the additional n-type column shielding layer.

8. The method according to claim 2, wherein
the forming of the p-type column based on the pattern deviation of the p-type column shielding layer includes:
measuring a width of the opening of the p-type column shielding layer;
implanting p-type impurity ions into the semiconductor layer through the opening of the p-type column shielding layer;
determining whether or not an additional implantation of the p-type impurity ions is necessary according to the measured width of the opening of the p-type column shielding layer;
forming an additional p-type column shielding layer having an opening corresponding to at least a portion of the p-type column formation range on the surface of the semiconductor layer when it is determined that the additional implantation of the p-type impurity ions is necessary; and
implanting the p-type impurity ions into the semiconductor layer through the opening of the additional p-type column shielding layer.

9. The method according to claim 1, wherein
the forming of the super junction structure includes:
forming an n-type column shielding layer having an opening corresponding to a n-type column formation range where at least one of the n-type columns is to be formed on the surface of the semiconductor layer;
measuring a misalignment of the n-type column shielding layer relative to a design pattern;
forming the n-type column by implanting n-type impurity ions into the semiconductor layer through the opening of the n-type column shielding layer;
forming a p-type column shielding layer having an opening corresponding to a p-type column formation range where at least one of the p-type columns is to be formed based on the measured misalignment of the n-type column shielding layer on the surface of the semiconductor layer; and
forming the p-type column by implanting p-type impurity ions into the semiconductor layer through the opening of the p-type column shielding layer.

10. The method according to claim 1, wherein
the forming of the super junction structure includes:
forming a p-type column shielding layer having an opening corresponding to a p-type column formation range where the p-type column is to be formed on the surface of the semiconductor layer;
measuring a misalignment of the p-type column shielding layer relative to a design pattern;
forming the p-type column by implanting p-type impurity ions into the semiconductor layer through the opening of the p-type column shielding layer;
forming an n-type column shielding layer having an opening corresponding to an n-type column formation range where the n-type column is to be formed based on the measured misalignment of the p-type column shielding layer on the surface of the semiconductor layer; and
forming the n-type column by implanting n-type impurity ions into the semiconductor layer through the opening of the n-type column shielding layer.
